(19) United States
(12) Patent Application Publication
(10) Pub. No.: US 2007/0044942 A1
(43) Pub. Date: Mar. 1, 2007

(54) Bottom plate of a radiator for a CPU

(76) Inventor: Xingwen Mou, Shenzhen (CN)

Correspondence Address: G. LINK Co.,LTD, 3550 Bell Road, MINOOKA, IL, 60447, US

(21) Appl. No.: 11/209,707

(22) Filed: Aug. 24, 2005

(51) Int. Cl. H05K 7/20

(52) U.S. Cl. 165/104.33; 165/80.3; 361/700

(57) ABSTRACT

A bottom plate of a radiator for a CPU in a computer includes a lower surface contacting with the CPU and an upper surface provides elongated protrusion parts and elongated grooves corresponding to a heat pipe. The radiator further includes a cooling core composed of a plurality of cooling fins, a fan support at upper side of the cooling core, a fan fixed to the fan support and a retainer. The cooling core provides a recess corresponding to the elongated protrusion parts. The radiator with the bottom plate has advantages such as low cost, high dissipation performance, suitable for using with low power CPU and high capability of heat accumulation with high performance against heat impact

### BACKGROUND OF THE INVENTION

1. Field of the Invention

The present invention is related to a radiator for a CPU (Central Processing Unit) in a computer and particularly to improvement for a radiator with a heat pipe welded with cooling fins.

2. Brief Description of the Related Art

The CPU is an important part of a computer and one of parts need high power. The CPU generates a great deal of heat during running and it is required to remove the generated heat in time. Otherwise, the CPU is affected and even more damaged. Usually, the radiator is used for removing the generated heat and it can be seen in FIG. 1 that a conventional radiator with heat pipe welded to cooling fins provides a flat bottom plate is welded to the heat pipe and the cooling fins. In order to obtaining better performance of the cooling fins, more heat pipes are used under a condition of providing greater thickness of the bottom plate. Under this principle, although performance of the cooling fins is enhanced, cost of the cooling fins increases largely due to expensive heat pipes. Next, contact area between the bottom plate and the cooling fins decreases in case of more heat pipes being disposed in parallel such that heat transfer effect of the radiator is degraded in accordance with increase of number of heat pipes. Further, in case of the radiator being used for low power CPU, the first choice is to reduce the number of the heat pipes for lowering the cost. But, the lower cooling fins leave holes for the removed heat pipe and the contact area between the bottom plate and the cooling fins is unable to increase even if less heat pipes are kept. It means keeping original heat pipes in place is better than part of the heat pipes are removed from the stand point of heat dissipation effect. However, the problem is the original radiator for low power CPU costs high.

### SUMMARY OF THE INVENTION

In order to solve the preceding problems resided in the bottom plate of the radiator, an object of the present invention is to provide a bottom plate of a radiator for a CPU with which good effect of heat dissipation and high capacity of heat accumulation can be obtained such that low cost radiator is capable of being offered.

Accordingly, a bottom plate of a radiator for a CPU in a computer includes a lower surface contacting with the CPU and an upper surface provides elongated protrusion parts and elongated grooves corresponding to a heat pipe. The radiator further includes a cooling core composed of a plurality of cooling fins, a fan support disposed at the upper side of the cooling core, a fan fixed to the fan support and a retainer passing two clearances at the center of the cooling core. The cooling fins are fixed to the upper surface and two lateral sides of the bottom plate. The cooling core provides a recess corresponding to the elongated protrusion parts. The radiator with the bottom plate has advantages such as low cost, high dissipation performance, suitable for using with low power CPU and high capability of heat accumulation with high performance against heat impact

### BRIEF DESCRIPTION OF THE DRAWINGS

The detail structure, the applied principle, the function and the effectiveness of the present invention can be more fully understood with reference to the following description and accompanying drawings, in which:

FIG. 1 is a perspective view of the conventional radiator for a CPU illustrating a radiator core composed of cooling fins, a heat pipe thereof;

FIG. 1A is a plan view of a bottom plate of the conventional radiator shown in FIG. 1;

FIG. 2 is a perspective view of bottom plate of a radiator for a CPU according to the present invention;

FIG. 3 is a perspective view of another bottom plate of a radiator for a CPU according to the present invention;

FIG. 4 is a plan view of a radiator for a CPU according to the present invention;

FIG. 5 is an exploded perspective view of a radiator for a CPU shown in FIG. 4; and

FIG. 6 is a perspective view of another radiator for a CPU according to the present invention.

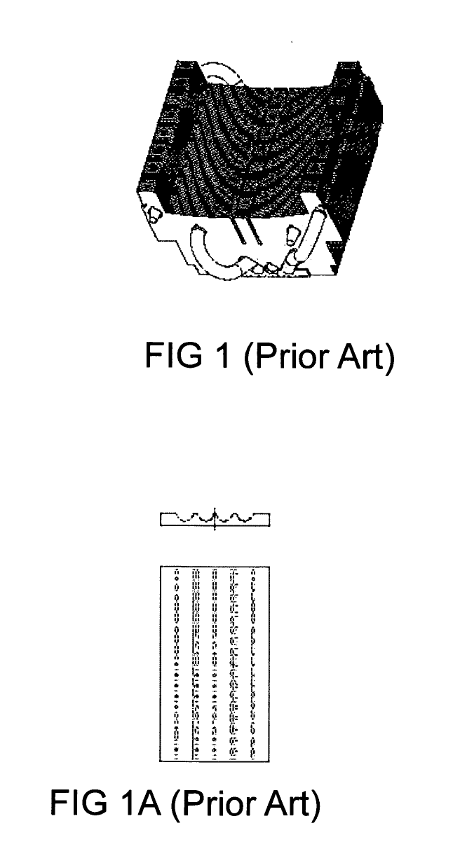

### DETAILED DESCRIPTION OF THE INVENTION

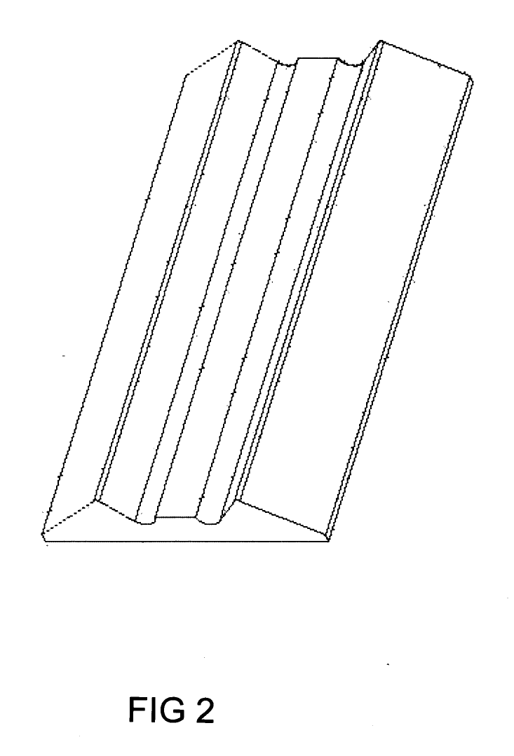

Referring to FIG. 2, a bottom plate of a radiator for a CPU according to the present invention includes a lower surface contacting with the CPU and an upper surface opposite the lower surface. The lower surface is a rectangular flat plane and the upper surface has four-side prism shaped protrusion at two opposite lateral sides thereof. There are two elongated arc grooves between the two protrusions.

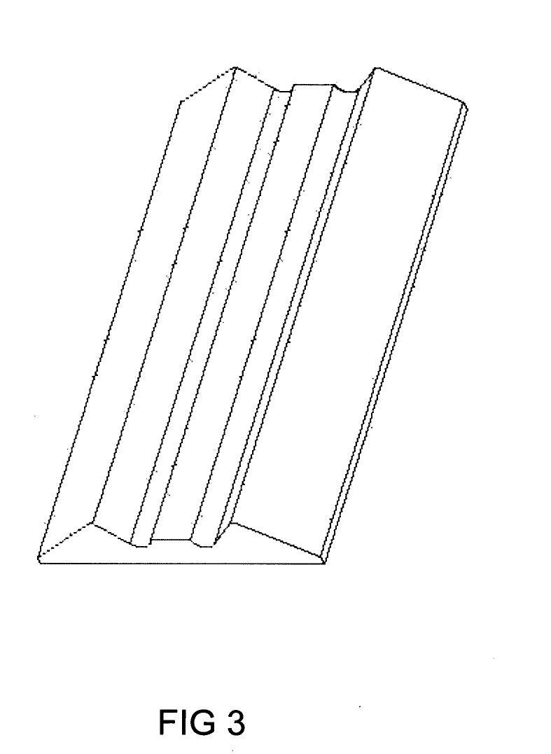

Referring to FIG. 3, another type of the bottom plate of the radiator for CPU according to the present invention shown in the figure includes a lower surface contacting with the CPU and an upper surface opposite the lower surface. The lower surface is a rectangular flat plane and the upper surface has a three-side prism shaped protrusion at two opposite lateral sides thereof respectively. There are two elongated arc grooves between the protrusions.

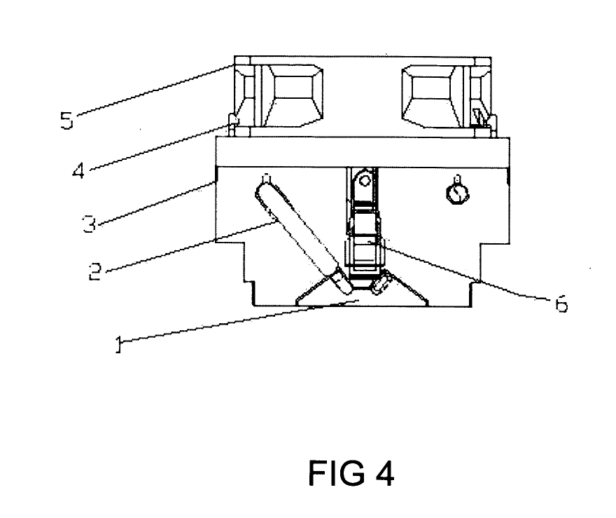

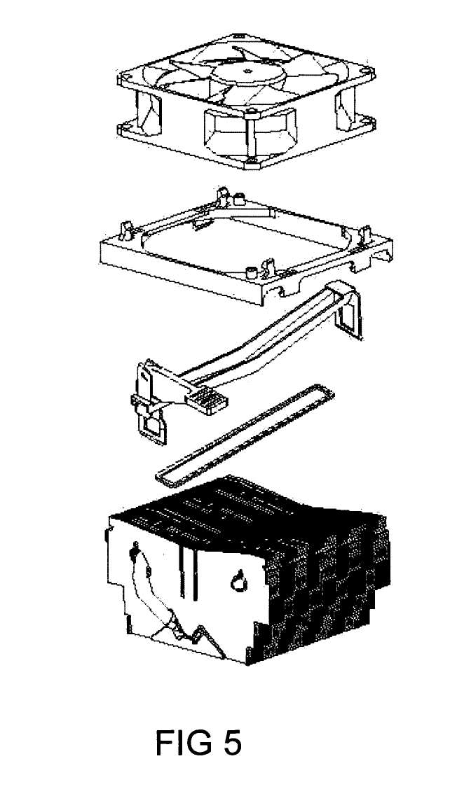

Referring to FIGS. 4 and 5, the radiator according to the present invention includes a bottom 1, a heat pipe 2, a cooling core 3, a fan support 5 and a fixing retainer 6. The bottom plate 1 is the same as the bottom shown in FIG. 2. The cooling core 3 is composed of a plurality of cooling fins with a recess at the lower side thereof corresponding to the two four-side prism shaped protrusions at the upper surface of the bottom plate 1. The cooling core 3 has two elongated narrow clearances at the center of the upper surface of the bottom plate 1 and the narrow clearances extend slightly over middle part of the cooling core 3. The cooling core 3 passes through and is fixed to the upper surface and the left and right lateral sides of the bottom plate 1. The heat pipe 2 passes through the arc grooves and returns to pass through a hole in the cooling core 1. The fan support fits with the outer side at the upper surface of the cooling core and the fan is mounted to the fan support with screws. The retainer 6 passes through the two narrow clearances and fits with the radiator.

When the bottom plate and the radiator for a CPU according to the present invention is installed, the lower surface of the bottom plate is coated with heat guide paste and the radiator passes through the retainer 6 to be fixedly attached to a base on the main board of a computer for the lower surface closely contacting with the CPU. Thus, heat generated from the CPU during the computer running is able to transmit to the bottom plate and then conduct to the cooling core and the heat pipe such that the heat radiates to air nearby via passing through the cooling core. Further, the fan removes hot air to promote heat dissipation. Because the four-side prism shaped protrusions on the upper surface of the bottom plate provides much better heat accumulation capability than the conventional flat bottom plate, stronger function of heat relay can be obtained while the CPU increases heat generation rapidly so that it enhances capability of the radiator against heat impact and prevents inactiveness of the heat pipe. Due to arrangement of the protrusions, more contact area of the bottom plate with the cooling fins is obtained than the conventional flat bottom plate so that heat dissipation efficiency is promoted substantially. Furthermore, under the same heat dissipation requirement, the bottom plate of the present invention needs less number of expensive heat pipes comparing to the flat bottom plate because of the protrusion part so that cost of the radiator is reduced significantly.

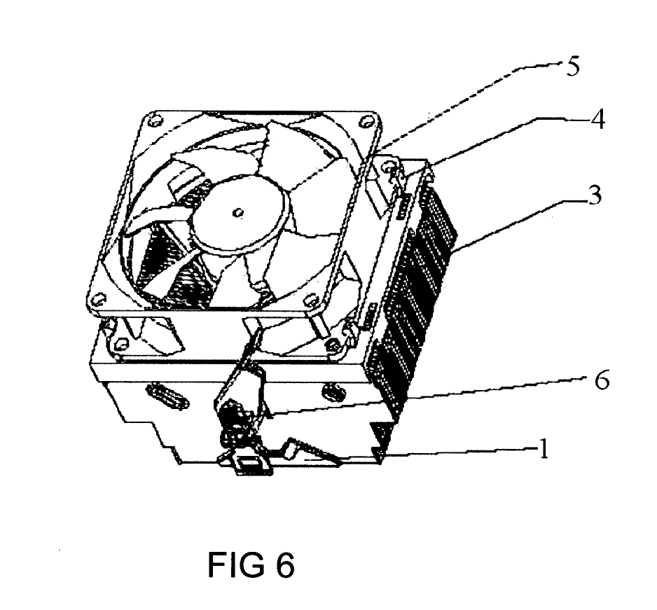

Referring to FIG. 6, another type radiator according to the present invention includes a bottom plate 1, a cooling core 3, a fan support 4, a fan 5 and a retainer 6. The bottom plate 1 is the floor shown in FIG. 3. The present type radiator is provided almost the same as the radiator shown in FIG. 2 unless being without the heat pipes. The present type radiator is low cost with good heat dissipation effect and can be used with low power CPU.

In addition, other type protrusion parts on the bottom plate of the invention can be provided and three or more protrusion parts can be used instead of two too.

It is appreciated that the bottom plate with a radiator for CPU according to the present invention has the following advantages:

1. Cost of product can be reduced tremendously.

2. Heat dissipation performance can be enhanced substantially;

3. It is suitable for low power CPU.

4. It provides high capability of heat accumulation with high performance against heat impact.

While the invention has been described with referencing to preferred embodiments thereof, it is to be understood that modifications or variations may be easily made without departing from the spirit of this invention, which is defined by the appended claims.

What is claimed is:

1. A bottom plate of a radiator for a CPU, comprising:
a lower surface, contacting with the CPU; and
an upper surface;
characterized in that a plurality of elongated protrusion parts are provided on the upper surface.

2. The bottom plate of a radiator for a CPU as defined in claim 1, wherein the elongated protrusion parts are two four-side prism shaped protrusion parts being disposed at two lateral sides of the bottom plates respectively.

3. The bottom plate of a radiator for a CPU as defined in claim 1, wherein the elongated protrusion parts are two three-side prism shaped protrusion parts being disposed at two lateral sides of the bottom plates respectively.

4. The bottom plate of a radiator for a CPU as defined in claim 1, wherein more than two four-side prism shaped protrusion parts are provided on the upper surface thereof.

5. The bottom plate of a radiator for a CPU as defined in claim 1, wherein more than three-side prism shaped protrusion parts are provided on the upper surface thereof.

6. The bottom plate of a radiator for a CPU as defined in claim 1, wherein the upper surface thereof provides two elongated are grooves.

7. A radiator for a CPU, comprising
A bottom plate, providing a plurality of elongated protrusions;
A cooling core, being composed of a plurality of cooling fins and disposed on the bottom and providing a plurality of holes;
A retainer, being passed through with the main body of the radiator;
A fan support, being attached to the upper side of the cooling core; and
A fan, being fixedly attached to the fan support;
characterized in that the bottom plate is described in claim 1 and a recess is provided at the lower side of the cooling core corresponding to the elongated protrusions.

8. The radiator for a CPU as defined in claim 1, wherein the bottom plate is the bottom plate described in claim 6 and a heat pipe is provided to pass through the arc grooves and the holes in the cooling core.
